(19) United States
(12) Patent Application Publication
(10) Pub. No.: US 2015/0208547 A1
(43) Pub. Date: Jul. 23, 2015

(54) Kinetic Heat-Sink with Non-Parallel Stationary Fins

(71) Applicant: CoolChip Technologies, Inc., Somerville, MA (US)

(72) Inventors: Lino A. Gonzalez, Somerville, MA (US); Florent Nicolas Séverac, Oakland, CA (US); Pramod Chamarthy, Plano, TX (US)

(21) Appl. No.: 14/601,612

(22) Filed: Jan. 21, 2015

Related U.S. Application Data
(60) Provisional application No. 61/930,535, filed on Jan. 23, 2014.

(51) Int. Cl. H05K 7/20

(52) U.S. Cl. CPC H05K 7/20154; H05K 7/20172; H05K 7/20409

(57) ABSTRACT

A base and a rotating structure together form a kinetic heat sink. The rotating structure has a movable heat extraction surface and plurality of rotating fins in thermal contact with the movable heat extraction surface. Each of the plurality of rotating fins has a radially outermost rotating fin-edge. The kinetic heat sink also has a plurality of stationary fins in thermal contact with the base. The plurality of stationary fins circumscribes the rotating fins. Each of the stationary fins has a stationary fin-edge that is its most radially inward portion. This plurality of stationary fin-edges and the plurality of rotating fin-edges form a circumferential fluid gap radially outward of the plurality of rotating fins. At least a portion of the stationary fin-edge of one or more of the stationary fins diverges from at least a portion of the rotating fin-edge of at least one of the rotating fins.

### PRIORITY

This patent application claims priority from provisional U.S. patent application No. 61/930,535, filed Jan. 23, 2014, entitled, “KINETIC HEAT-SINK WITH NON-PARALLEL STATIONARY FINS,” and naming Florent Nicolas Severac, Lino A. Gonzalez, and Pramod Chamarthy as inventors, the disclosure of which is incorporated herein, in its entirety, by reference.

### FIELD OF THE INVENTION

The present invention relates to kinetic heat sinks and, more particularly, the present invention relates to kinetic heat sinks having stationary and rotational cooling fins.

### BACKGROUND OF THE INVENTION

As electronic devices are furnished with more processing-power, they typically generate more waste-heat. In certain consumer electronic devices, such as game consoles, conventional cooling solutions often are at their upper limits in meeting their primary requirements—removing waste-heat. Compounding this concern, efficient heat removal often requires tradeoffs that can lead to other problems, such as increased noise or size limitations.

To increase heat-transfer capacity, a conventional convective cooling apparatus, such as finned heat-sinks coupled with fans, may be designed such that the heat-sink (i.e., thermal mass) is larger or geometrically denser (e.g., more cooling surface area), or such that the fan operates at high rotation speed, or both. For certain applications, such a cooling apparatus cannot meet all the requirements of heat-transfer capacity, noise-output, size, etc. Other methods, such as liquid cooling, are prone to leaking —thus adding risk and additional cost.

### SUMMARY OF VARIOUS EMBODIMENTS

In accordance with one embodiment of the invention, a base is rotatably coupled with a rotating structure to form a kinetic heat sink. The rotating structure has a movable heat-extraction surface spaced from and facing the base across a longitudinal fluid gap, and the rotating structure has a plurality of rotating fins in thermal contact with the movable heat extraction surface. The rotating fins are configured to move fluid, and each of the plurality of rotating fins has a rotating fin-edge. In a corresponding manner, the kinetic heat sink also has a plurality of stationary fins in thermal contact with the base. The plurality of stationary fins are positioned radially outward of the rotating fins, and each of the plurality of stationary fins has a stationary fin-edge that acts as its most radially inward portion. The plurality of stationary fin-edges and the plurality of rotating fin-edges form a circumferential fluid gap radially outward of the plurality of rotating fins. At least a portion of the stationary fin-edge of one of the stationary fins is non-parallel to at least a portion of the rotating fin-edge of at least one of the rotating fins.

At least a portion of the stationary fin-edge of at least one of the stationary fins may be substantially perpendicular to at least a portion of the rotating fin-edge of at least one of the rotating fins. In that case, the stationary fin-edges of the plurality of stationary fins may be substantially perpendicular to the rotating fin-edges of the plurality of rotating fins.

The base may have a generally planar top base surface facing the rotating structure, and each of the plurality of stationary fin-edges may have at least a portion that forms an angle of between about 0 and 60 degrees with the generally planar top base surface.

Some embodiments of the movable heat-extraction surface have a rotatable, generally planar top surface configured to rotate in a rotation plane. In that case, each of the plurality of rotating fin-edges may have at least a portion that is substantially perpendicular to the rotation plane. In addition or alternatively, each of the plurality of stationary fin-edges may have at least a portion that is substantially parallel to the rotation plane of the movable heat-extraction surface. More generally, each of the plurality of stationary fin-edges may at least a portion that forms an angle of between about 0 and 60 degrees with the rotation plane of the movable heat-extraction surface.

Each of the rotating fins may have a face with an upper and lower portion relative to the generally planar top surface. In that case, each of the rotating fins may have an upper width nearer its upper portion and a lower, larger width nearer its lower portion. In fact, each of the plurality of rotating fins may have a substantially identical cross-sectional shape in planes parallel to the rotation plane.

In a corresponding manner, each of the stationary fins may have a face with an upper and lower portion relative to the generally planar top base surface. Each of the stationary fins may have an upper width nearer its upper portion and a lower, larger width nearer its lower portion to form a tapering stationary fin-edge. Moreover, each rotating fin may have a tapering rotating fin-edge and each stationary fin may have a tapering stationary fin-edge.

The plurality of rotating fins may be in conductive heat contact with the movable heat extraction surface, and/or the plurality of stationary fins may be in conductive heat contact with the base.

To facilitate heat transmission, the kinetic heat sink may have a heat-spreading member convectively coupled between the base and the stationary fins. Moreover, because the rotating structure preferably is configured to rotate to move fluid, the plurality of stationary fins may be oriented and configured to dissipate heat when in contact with the fluid moved by the plurality of rotating fins.

Among other distances, the longitudinal fluid gap may be less than about 150 micrometers, and/or at least a portion of the circumferential fluid gap may be at least about 2 millimeters. Some embodiments form the stationary fins as a stacked plurality of ring shaped members having faces that are substantially parallel to the base. To mitigate radial fluid flow resistance, each stationary fin preferably is spaced from the other stationary fins.

In accordance with another embodiment of the invention, a base and a rotating structure (rotatably coupled with the base) together form a kinetic heat sink. The rotating structure has a movable heat extraction surface and plurality of rotating fins in thermally conductive contact with the movable heat extraction surface. Each of the plurality of rotating fins has a radially outermost rotating fin-edge. The kinetic heat sink also has a plurality of stationary fins in thermally conductive contact with the base. The plurality of stationary fins circumscribes the plurality of rotating fins. Each of the plurality of stationary fins has a stationary fin-edge that is its most radially inward portion. This plurality of stationary fin-edges and the plurality of rotating fin-edges form a circumferential fluid gap radially outward of the plurality of rotating fins. At least a portion of the stationary fin-edge of one or more of the stationary fins diverges from at least a portion of the rotating fin-edge of at least one of the rotating fins.

In accordance with other embodiments of the invention, a base and a coupled rotating structure (rotatably coupled with the base) together form a kinetic heat sink. The rotating structure has a generally planar rotatable heat extraction surface, and plurality of rotating fins in thermally conductive contact with the rotatable heat extraction surface. Each of the plurality of rotating fins has a radially outermost rotating fin-edge that is substantially perpendicular to the planar rotatable heat extraction surface. The kinetic heat sink also has a plurality of stationary fins in thermally conductive contact with the base. The plurality of stationary fins circumscribes the plurality of rotating fins, and each of the plurality of stationary fins has a stationary fin-edge that is its most radially inward portion. The plurality of stationary fin-edges and plurality of rotating fin-edges form a circumferential fluid gap radially outward of the plurality of rotating fins. At least a portion of the stationary fin-edge of one or more of the stationary fins forms an angle of between about 30 and 90 degrees with the rotating fin-edge of one or more of the rotating fins.

### BRIEF DESCRIPTION OF THE DRAWINGS

The foregoing features of embodiments will be more readily understood by references to the following detailed description, taken with reference to the accompanying drawings, in which:

FIG. 1 schematically shows a top perspective view of a kinetic heat-sink with stationary and rotating fins according to an illustrative embodiment of the invention.

FIG. 2 schematically shows a cross-sectional view of the kinetic heat-sink of FIG. 1.

FIG. 3 illustrates heat-transfer performance of a kinetic heat-sink with stationary and rotating fins according to an illustrative embodiment of the invention.

FIG. 4 schematically shows a cross-sectional view of a kinetic heat-sink with stationary fins according to another embodiment of the invention.

FIGS. 5-7 schematically show examples of the rotating structure of the kinetic heat-sink according to the various embodiments.

FIGS. 8-10 schematically show different views of orthogonally-oriented stationary-fins, according to an embodiment of the invention.

FIGS. 11-12 schematically show different views of a kinetic heat-sink with horizontal stationary fins according to an alternative embodiment.

FIGS. 13-14 schematically show different views of a kinetic heat-sink with a housing according to an embodiment of the invention.

FIG. 15 schematically shows a cross-sectional view of a kinetic heat-sink with orthogonally-oriented stationary fins according to another embodiment.

FIG. 16 schematically shows a cross-sectional view of a kinetic heat-sink with angled stationary fins according to another embodiment.

FIG. 17 schematically shows a cross-sectional view of a kinetic heat-sink with angled stationary fins according to an alternative embodiment.

FIG. 18 schematically shows cross-sectional view of a kinetic heat-sink with angled rotating fins according to another embodiment.

FIGS. 19-22 schematically show different views of a kinetic heat-sink with angled stationary fins according to an alternative embodiment.

FIG. 23 is a schematic diagram illustrating a thermal-resistance model of the kinetic heat-sink with stationary fins according to an illustrative embodiment of the invention.

FIG. 24 shows a method of operating a kinetic heat-sink with stationary fins according to an illustrative embodiment of the invention.

### DESCRIPTION OF ILLUSTRATIVE EMBODIMENTS

In illustrative embodiments, a kinetic heat-sink has a thermal base (for thermal contact with a heat-generating component), which both (i) rotatably couples to a rotating structure with fins and (ii) fixably couples to stationary fins that are mounted in a non-parallel orientation relative to the fins on the rotating structure. The kinetic heat-sink thus enables high-density heat-transfer and yet, maintains a relatively small-footprint and relatively low-noise-output. Details of various embodiments are discussed below.

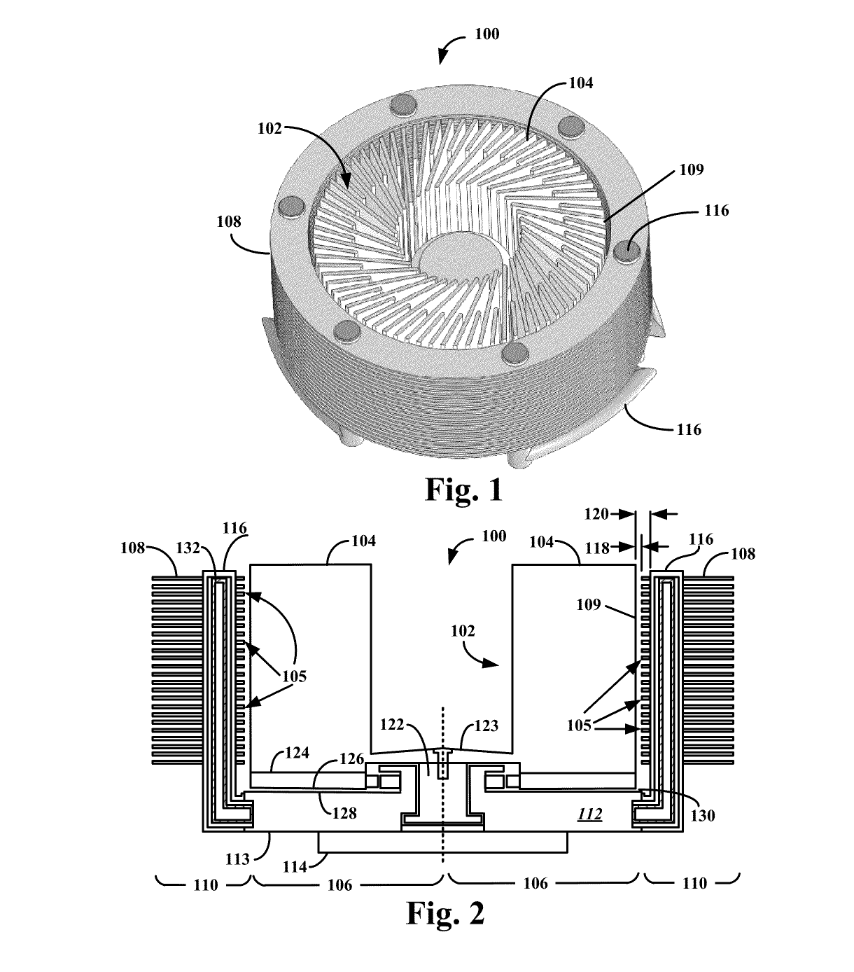

FIG. 1 schematically shows a top perspective view of a kinetic heat sink 100 with stationary fins configured according to an illustrative embodiment of the invention. FIG. 2 schematically shows a cross-sectional view of the same kinetic heat sink 100 generally across its center. In a manner similar to other like devices, the kinetic heat sink 100 has a rotating structure 102 that is rotatably coupled with a stationary base structure 112. To facilitate heat transfer, the rotating structure 102 has a plurality of rotating fins 104 at a first radial location 106. In a corresponding manner, the base structure 112 thermally couples with a plurality of stationary fins 108 at a second radial location 110. The stationary fins 108 thus collectively surround (i.e., circumscribe—not necessarily forming a circle though) the rotating fins 104. In other words, the second radial location 110 is radial outward of the first radial location 106. Both the rotating structure 102 and the stationary fins 108 thus thermally couple to a thermal base structure 112. In illustrative embodiments the stationary fins 108 form a thermally conductive connection to the base. During use, the base structure 112 may be mounted to a heat-generating component 114, such as a microprocessor.

As shown in FIGS. 1 and 2, the plurality of rotating fins 104 are spaced from the plurality of stationary fins 108 to effectively form a thin circumferential fluid gap 118 or region therebetween. The circumferential fluid gap 118 can take on a number of volumetric shapes, such as generally annular shape, or an irregular shape. Those skilled in the art can select an appropriate spacing based on thermal benefits and fluid resistance, among other things. For example, the circumferential fluid gap 118 can have a spacing of about 0.5 to 5 millimeters in various locations (e.g., 2 millimeters or between about 2 and 3 millimeters). Some embodiments may form the circumferential fluid gap 118 to have substantially uniform inner and outer diameters, a varying inner diameter with a uniform outer diameter, or a uniform inner diameter with a varying outer diameter. Of course, those skilled in the art may modify those distances and shapes based on the application.

At the first radial location 106, the rotating structure 102 rotatably couples to the thermal base structure 112 such that it can freely rotate. As the rotating structure 102 rotates, it generates fluid flow (e.g., air flow) in channels formed between fluid-directing structures (i.e., the rotating fins 104) within the rotating structure 102. The fluid flows radially outward from the rotating structure 102, mainly due to centrifugal mechanisms to surrounding areas in communication with the rotating structure 102. A thermal gradient forms, transferring heat from the base structure 112 to the rotating structure 102 as described in co-pending U.S. patent application Ser. No. 13/911,677, the disclosure of which, is incorporated herein, in its entirety, by reference.

As discussed in more detail in that patent application, the rotating structure 102 has a generally planar rotatable heat-extraction surface126 that is generally parallel and facing the generally planar thermal base structure 112. In other words, the surfaces 112 and 126 are directed toward each other and, in this embodiment, have no intervening elements—just air. As such, the rotatable heat-extraction surface 126 rotates in a rotational plane that, in illustrative embodiments, is generally parallel with the facing surface of the thermal base structure 112. As discussed in greater detail in that application and below, the heat extraction surface 126 and thermal base structure are spaced apart to form a longitudinal fluid gap 130. In illustrative embodiments, the longitudinal fluid gap 130 is sized to transfer heat from the thermal base structure 112 to the heat extraction surface 126.

Indeed, some embodiments use additional or alternative heat transfer modalities across the longitudinal fluid gap 130. For example, the kinetic heat sink 100 can have generally concentric rings extending into longitudinal fluid gap 130 from the heat-extraction surface 126 and the planar base structure 112. Some details of such a modality are shown in co-pending the PCT Patent application having International Patent Application Number PCT/US14/51987, filed on Aug. 21, 2014, the disclosure of which is incorporated herein, in its entirety, by reference.

The rotating fins 104 preferably extend from the platen/rotating core structure 124 that forms the heat-extraction surface 126. Specifically, in the embodiment shown, the rotating fins 104 extend from the side opposite to that of the heat extracting surface 126. Heat thus traverses from the thermal base structure 112, across the longitudinal fluid gap 130, to the heat extraction surface 126 via the longitudinal fluid gap 130, and through the rotating fins 104, and to the environment/thermal reservoir (i.e., the environment surrounding the kinetic heat sink 100, such as a large, air conditioned room).

The base structure 112 also thermally transfers heat, via conduction, to the stationary fins 108. Accordingly, as the fluid (e.g., air) generated by the rotating fins 104 flows generally radially outwardly, it contacts and passes the stationary fins 108 at the second radial location 110. Accordingly, this waste-heat, from both the stationary and rotating fins 104 and 108, is subsequently rejected into the larger thermal reservoir. As suggested, the thermal reservoir is generally a space or environment having a relatively large thermal mass compared to a kinetic heat-sink and additionally may include a thermal bath, or ambient air in which the kinetic heat-sink 100 may sit.

The set of stationary fins 108 increases the heat-transfer capacity of the sink 100 by providing additional heat-transfer surface area. To leverage the higher velocity fluid flow outputted from the rotating fins 104, the stationary fins 108 may be positioned close to the rotating fins 104—reducing the thickness or outer dimension of the circumferential gap. When placed in close proximity to the rotating structure 102, however, the inventors found that the stationary fins, in certain orientations, can create disturbances in the output flow from the rotating structure 102, which undesirably produces acoustic noise. For example, the inventors noticed that when several such fins are employed and repeated in a spatially uniform manner, they can create the disturbances at the same time interval that accentuate an acoustic noise at a particular period (i.e., 1/frequency). As such, some embodiments form narrow-band noise, which can be quite annoying and disturbing to people in the environment. During operation, this resulting acoustic noise can be over 9 decibels (dB) higher than the background noise.

In solving this problem, the inventors discovered that when orienting the stationary fins 108 in an angled, diverging, or non-parallel configuration relative to the rotating impeller fins, the airflow passes the stationary fins 108 in a less disturbed manner, consequently producing less narrow-band acoustic noise. Indeed, while mitigating this narrow-band noise, illustrative embodiments are expected to continue to have broadband noise, which typically is less offensive to people in the environment.

In particular, as the rotating fins 104 rotate, centrifugal mechanisms radially expel the air between the fins 104. This airflow has radial, angular, and axial components as it is directed from the edges 109 of the rotating fins 104, with the latter being smaller in magnitude than the other two. When opposing surfaces of another structure (such as the stationary fins 108) are proximally/closely located to that edge 109, pulsating flow from the relative movement of the rotating fins may impinge onto the stationary structure unless the angle of the stationary structure matches the angle of the airflow at all angular locations. This results in localized pressure variations, generating the acoustic noise. The inventors discovered that they can minimize or reduce these highly localized pressure fluctuations by orienting at least a portion of the two passing structures to be non-parallel to one another.

More specifically, each of the stationary fins 108 and the rotating fins 104 is considered to have length, a width, and a thickness. The width and length together form relatively large front and back faces of the fin 104 or 108, which are separated by its thickness. In illustrative embodiments, the thickness is significantly smaller than the dimensions of the length and width. The fins 104 and 108 thus are considered to form edges at the outer periphery of their respective faces. For example, one edge is the rotating fin-edge 109 mentioned above. The stationary fins 108 correspondingly form stationary fin-edges 105.

As shown more clearly in FIG. 2, in some embodiments the rotating fin-edges 109 and stationary fin-edges 105 generally define the circumferential gap 118. More specifically, for each rotating fin 104, the outermost rotating fin-edge 109 is the edge that is positioned the radially farthest from the center of the kinetic heat sink 100. It often is the radially outermost portion of the fin 104 itself. In a similar manner, for each stationary fin 108, the innermost stationary fin-edge 105 is positioned the edge that is radially farthest inward toward the center of the kinetic heat sink 100. It often is the radially innermost portion of the fin108 itself. Moreover, while a fin-edge 105 or 109 may be generally straight, some embodiments are curved or have a non-straight shape (e.g., form two or more line segments). In either case, in preferred embodiments, the cross-sectional shape of the fin 105 or 108 remains the same. Specifically, in some embodiments, at least one fin 105 or 109 has a substantially identical cross-sectional shape when sectioned by planes generally parallel to the rotation plane of the rotating structure 102.

The relative orientation/angle between the two passing structures (i.e., the respective edges 109 and 105 of the rotating and stationary fins 104 and 108) preferably is between about 15 and 90 degrees. Preferred embodiments orient the stationary fins-edges 105 to be substantially perpendicular/orthogonal to (i.e., about 90 degrees) the edges 109 of the rotating fins 104, or the angular flow of such fins 108. For example, in the embodiment shown in FIGS. 1 and 2, the faces of the stationary fins108 are generally parallel with the base structure 112—formed as a plurality of stacked, spaced thermally conductive rings. As such, the stationary fin-edges 105 are generally perpendicular to the edges 109 of the rotating fins 104.

As discussed above and below, the edges 105 and 109 may take on other non-parallel relationships. For example, the edges 105 and 109 may diverge to form angles of between 15 and 90 degrees. For example, at least a portion of some of the rotating fin-edges 109 may form a 90 degree angle with the generally planar base structure 112 or the generally planar heat extraction surface 126. It should be noted that surfaces with some details or irregularities may be considered to form a planar surface despite not having a perfectly smooth surface.

At least a portion of some of the stationary-fin-edges 105 thus may form a 90 degree angle with the rotating fin-edges 109, or other smaller angles, such as 30 degrees, 45 degrees, 60 degrees, or other angle between 30 and 90 degrees. Some embodiments may form smaller angles than 30 degrees, such as 15 or 20 degrees. Those skilled in the art can select the appropriate angle for a given application.

Although the stationary fins 108 may directly extend from the thermal base structure 112, some embodiments may be supported by heat-spreading structures 116, such as heat pipes or other thermal conducting bodies. In such embodiments, like the stationary fins 108, the nearest surface of the heat-spreading structures 116 is preferably located radially outwardly of the rotating fins 104. The distance 120 between the heat-spreading structures 116 and the rotating fins 104 may measure preferably at least about 5 mm more than the circumferential gap 118. The additional distance 120 may reduce the magnitude of the acoustic noise generated between the rotating fins 104 and the heat-spreading structure 116. In addition, illustrative embodiments have fewer heat-spreading structures 116 than stationary fins 108, although some embodiments may have an equal number or more.

The heat-transfer capacity of the kinetic heat sink primarily results from heat rejection by both the rotating fins 104 and the stationary fins 108. The ratio of surface area between the stationary and rotating fins 108 and 104 may be selected based on the amount of cooling desired. For example, in high-density thermal management applications, the ratio of the surface area between the stationary fins 108 and the rotating fins 104 may be between about 0.4 and 0.6, although it may be greater than one. In certain embodiments, the surface area of the stationary fins measures preferably between about 300 and 2000 cm² while the surface area of the rotating fins 104 measures preferably between about 300 and 2000 cm². To this end, the footprint area of the stationary fins 108 on the thermal base 112 measures preferably between 30 and 200 cm² while that of the rotating fins 104 measures preferably between 30 and 200 cm². Such footprints may correspond to the first and second radial locations 106, 110.

The heat-transfer capacity from a heat rejection surface (e.g., fins), of a heat sink to a transfer-fluid (e.g., air), may be expressed as Q, as shown in Equation 1,

Q=h A·ΔT (Equation 1)

where the amount of heat-transferred (Q) is a function of an effective heat-transfer coefficient (h), a heat-transfer area (A), and a temperature difference between the heat-rejection surface and the transfer-fluid (ΔT).

A kinetic heat-sink may have an h value between about 200 and 300 (in generating turbulent flow) as compared to force-cooled heat-sink, which may have a value between 50 and 150 (in generating laminar flow). A conventional force-cooled heat-sink generally includes a fan component mounted to a heat sink, which in turn is mounted to a heat source. The heat sink extracts heat from the heat source while the fan rotates, generating airflow, which rejects the extracted heat to the ambient air. Kinetic heat-sinks combine the benefits of a heat sink and fan into a single component. In doing so, illustrative embodiments produce higher fluid velocity across its heat rejection surfaces (e.g., fins) for the same rotational speed. Thus, kinetic heat-sinks configured in accordance with illustrative embodiments generally have a higher heat-transfer coefficient.

The effective heat-transfer coefficient (h) may be expressed as a function of the thermal conductivity of the transfer fluid (k), the Nusselt number (Nu), and the hydraulic diameter (D-h), as shown in Equation 2.

$$h = \frac{k}{D - h} Nu \qquad ( Equation 2 )$$

For applications where air is the transfer medium, thermal conductivity of the transfer fluid (k) may have a value about 0.0264 Wm⁻¹C⁻¹. Of course, other transfer mediums may be employed.

To this end, the kinetic heat-sink 100 with rotating fins 104 and stationary fins 108 has a first heat-transfer component for the rotating fins 104 (Q:Rotating_fins) and a second heat-transfer component for the stationary fins 108 (Q:Stationary_fins). Equation 3 is the total heat-transfer capacity (Q:total) of a kinetic heat-sink 100 with stationary fins 108.

Q:total=Q:Rotating_fins+Q:Stationary_fins (Equation 3)

Equation 3 may be expanded using Equation 1, resulting in Equation 4.

Q:total=h:rotating_finsA:rotation_fins·ΔT:rotating_fins+h:stationary_fins A:stationary_fins·ΔT:stationary_fins (Equation 4)

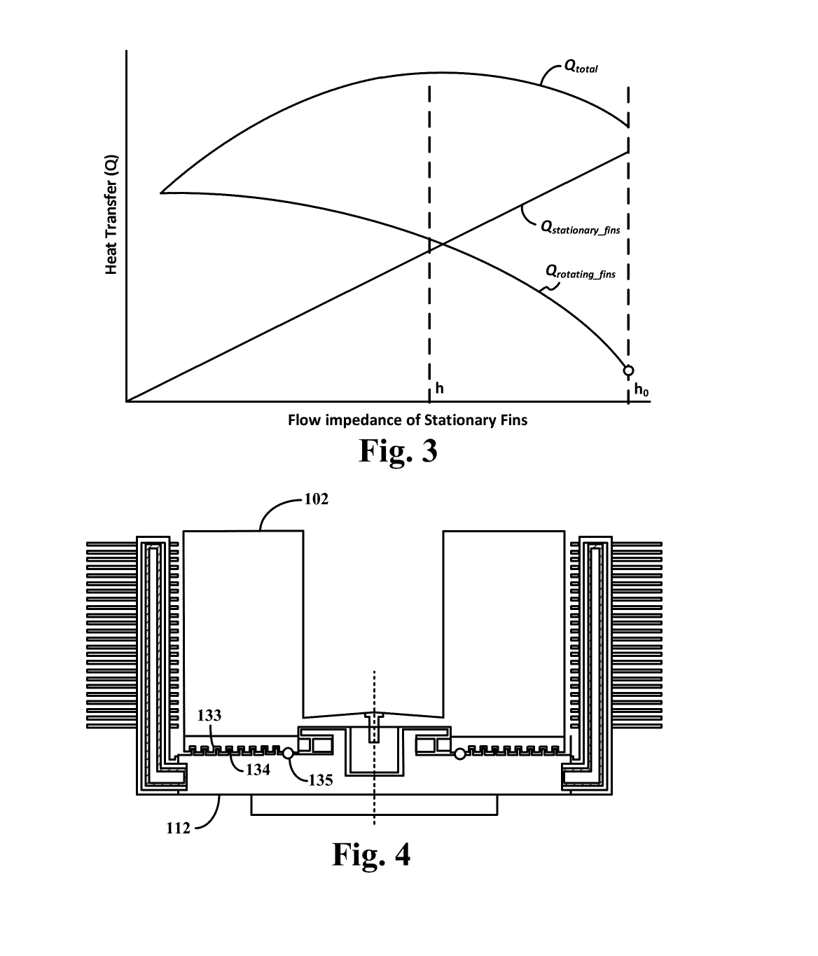

FIG. 3 graphically illustrates heat-transfer performance of a kinetic heat-sink 100 configured according to an illustrative embodiment of the invention. The stationary fins 108 provide additional area for heat transfer (A:stationary_fin), which may be balanced with the increased impedance added by the stationary fins 108. Although having increased impedance to the flow of heat-transferring fluid (thus reducing the heat-transfer coefficient of the kinetic portion of the heat sink (h:rotating_fins)), the inventors found that the overall heat-transfer performance (Q:total) of the kinetic heat-sink 100 with stationary fins 108 may be increased with respect to a similarly-sized kinetic heat-sink without the stationary fins. Specifically, as the flow impedance of the stationary fins 108 increases, the heat-transfer performance of the stationary fins 108 (Q:Stationary_fins) also increases while the heat-transfer performance of the rotating structure 102 of the heat sink 100 deceases (Q:Stationary_fins). Consequently, an optimum stationary fin configuration may maximize the total heat-transfer performance.

Referring back to FIG. 2, the thermal base structure 112 directly contacts the heat-generating component 114 in a thermally conductive manner such that a heat-conduction relationship exists between them, including through a thermal interface layer or a thermally conductive adhesive. To enhance thermal conduction, some embodiments apply a thermal film, such as thermal paste or thermal grease, between the base structure 112 and the heat-generating component 114 to mitigate any potential air pockets between the two elements 112, 114. The base structure 112 may mount, for example, via adhesives, screws, bolts, clamps, and fasteners, to a printed circuit board supporting the heat-generating component 114.

As noted above, the heat-generating component 114 may include, among other things, a processing component and is mounted to a printed circuit board or a socket supported on the board. The processing components may include a central processing unit (CPU), a graphics processing unit (GPU), a digital signal processing (DSP) unit, a field programmable gate array (FPGA), a system-on-a-chip (SOC), a microprocessor, or in a sick with a processor core, in a single chip package. Of course, other heat generating electronic components, such as power-integrated circuits, may be thermally managed using the various embodiments described.

The kinetic heat-sink 100 effectively includes a motor assembly 122 having a rotating component and a stationary component. The rotating component (e.g., having permanent magnets) is fixedly attached to the above noted rotating structure 102, while the stationary component (such as a stator) is fixedly attached to the base structure 112. The motor assembly 122 may be configured with various types of motors. For example, the motor assembly 122 may include: direct-current (DC) based motors such as brushed DC motors, permanent-magnet electric motors, brushless DC motors, switched reluctance motors, coreless DC motors, universal motors; or alternating-current (AC) based motors such as single-phase synchronous motors, poly-phase synchronous motors, AC induction motors, and stepper motors.

The stationary components of the motor assembly 122 may include a motor housing or a motor-housing. The stationary components also include motor windings to form the stator. The rotating components may include a clamp 123 (see FIG. 2) to couple the rotor portion of the motor assembly to the rotating fins 104. The rotating components may include permanent magnets that magnetically couple with the windings of the stator.

The rotating structure 102 may include the prior noted platen region 124 from which the rotating fins 104 extend. Specifically, the platen region 124 may include the prior noted heat extraction surface 126 (or heat transfer surface 126) that faces and is adjacent to a top facing surface 128 (from the perspective of FIG. 2) of the base structure 112 to form the noted longitudinal fluid gap 130. The gap 130 is preferably filled with ambient air and measures preferably less than about 100 μm, even more preferably between about 10 and 50 μm, and even more preferably between about 10 and 20 μm. The longitudinal fluid gap 130 may have a thermal-resistance characteristic measuring less than 0.1 degree Celsius per Watt (° C./W).

Other longitudinal fluid gap topologies may be employed with varying sizes. In certain embodiments, for example, the heat-transfer surface 126 may be a horizontal surface that is generally parallel (i.e., within anticipated tolerances, such as one or two degrees) to the base surface 128, which is also generally horizontal (e.g., within tolerances).

In other embodiments, the heat-transfer surfaces 126, 128 may form concentric rings extending from their surfaces that interdigitate with each other. In such embodiments, the longitudinal fluid gap 130 may be larger depending on the degree of overlapping between the two structures. In certain configurations, a longitudinal fluid gap having a clearance larger by a factor of two or three as described above may be employed.

FIG. 4 shows, for example, a kinetic heat-sink 100 with non-parallel stationary fins 108 and a rotating structure 102 having a first set of fins 133 interdigitated with second set of fins 134 of the base structure 112 according to an embodiment. This interdigitation may have a corrugated appearance. The rotating structure 102 may be offset from the thermal base 112 by mechanical bearings 135, which may maintain the longitudinal fluid gap 130 and the centricity of rotation of the rotating structure 102. As noted above, examples of various configurations of interdigitated fins are described the above referenced International Patent Application No. PCT/US14/51987.

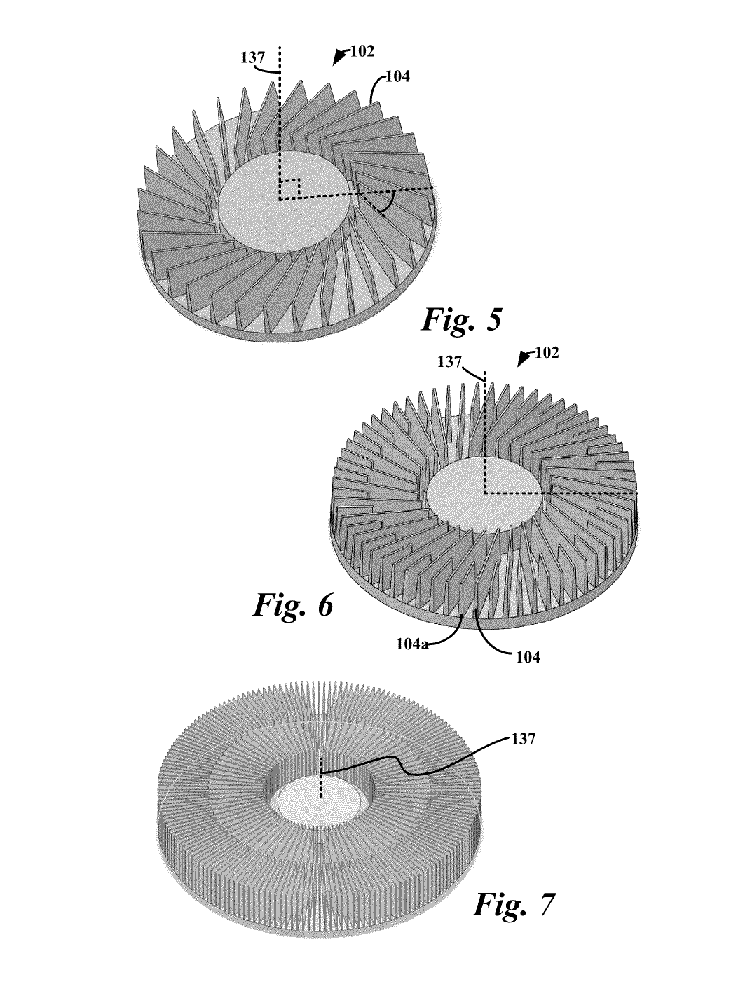

FIGS. 5-7 show examples of the rotating structure 102 and rotating fins 104 of the kinetic heat-sink 100. FIG. 5, for example, shows rotating fins 104 angled along a radial plane with respect to the center axis of the structure 102. FIG. 6 shows a second set of shorter rotating fins 104a positioned between the rotating fins 104 of FIG. 5. FIG. 7 shows two sets of rotating fins 104—long and short—that are both in parallel to the axis that traverse the rotational axis 137 of the rotating structure 102. In certain embodiments, the spacing between the various rotating fins 104 may measure preferably between about 0.5 and 5 mm, such as between about 0.5 and 2 mm.

With reference again to FIG. 2, the stationary fins 108 may be spaced to maximize the heat-transfer surface-area such that they do not substantially increase the airflow impedance through the fins 108. In a preferred embodiment, the stationary fins 108 are spaced between about 0.5 and 5 mm, such as between about 1 and 3 mm. Each of these stationary fins may have a thickness measuring preferably between about 0.3 and 2 mm, such as between about 0.3 and 0.5 mm.

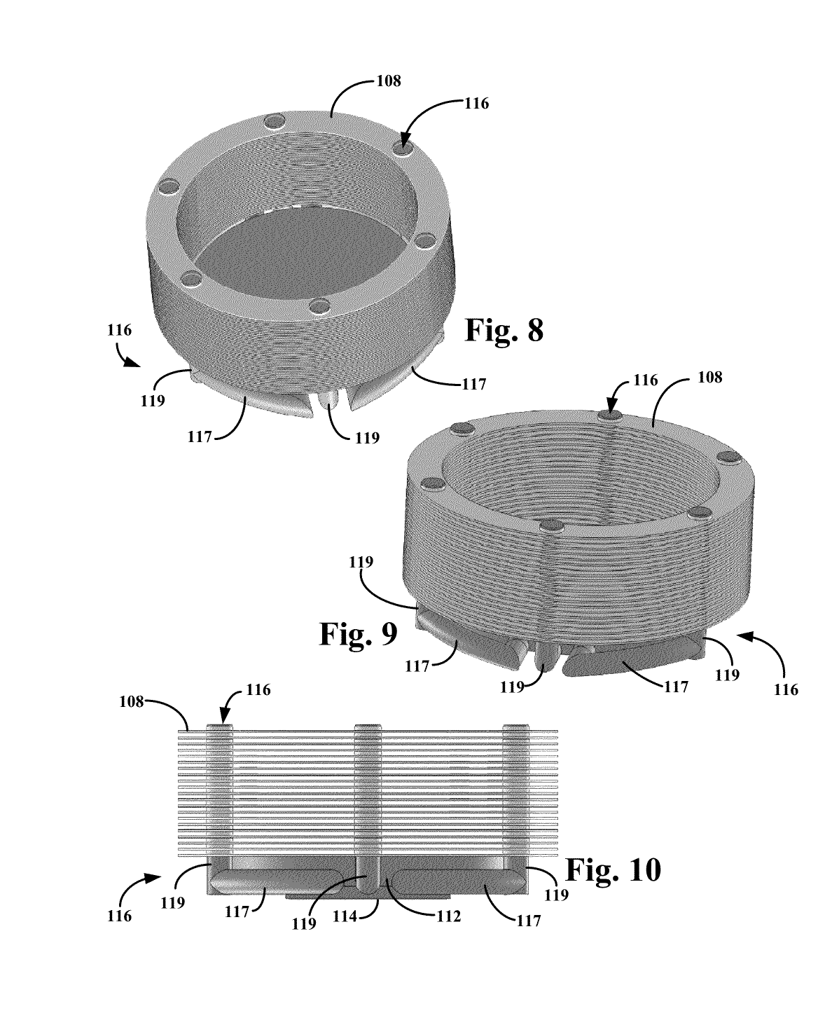

FIGS. 8-10 show different views of orthogonally-oriented stationary fins 108 (relative to the rotating fin-edges 109, which are fixably attached to the thermal base structure 112 through the heat-spreading structures 116, according to an illustrative embodiment of the invention. The kinetic heat-sink 100 may include at least two heat-spreading structures 116, or between two and twelve, or between six and eight. As noted above, the heat-spreading structures 116 may include a heat-pipe fixably attached to the base structure 112. The heat-spreading structures 116 may extend, for example, from the side of the base structure 112. Alternatively, some of the heat pipe may include a horizontal portion 117 and a vertical portion 119.

As known by those in the art, a heat pipe may be a sealed hollow heat-transfer device that employs thermal conductivity and phase transition to transfer heat between the two solid interfaces. The heat-pipe may include a fluid configured to transition, for example, between liquid and gaseous states in the seal-structure. Generally, heat may be applied to one side of the heat-pipe to convert the liquid to vapor, which then flows to a different portion of the heat-pipe. At that portion of the heat-pipe, which has lower temperature than the first portion, the vapor condenses back to the liquid state and flows back to the first portion of the heat-pipe. The heat-pipe may include capillary structures 132 (see FIGS. 2 and 4), such as, for example, wicks.

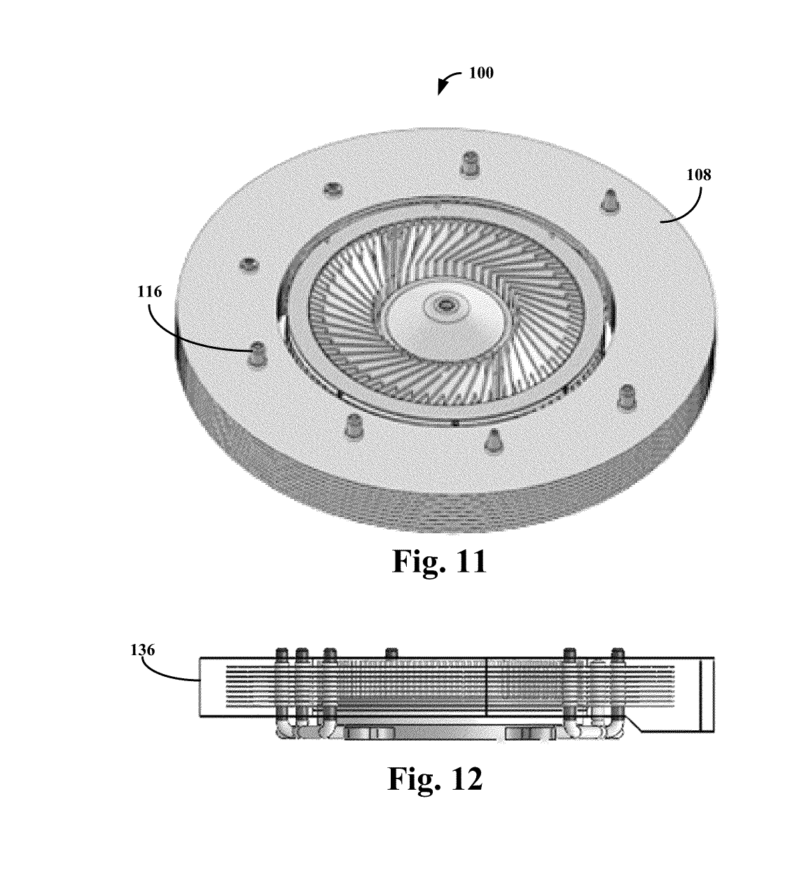

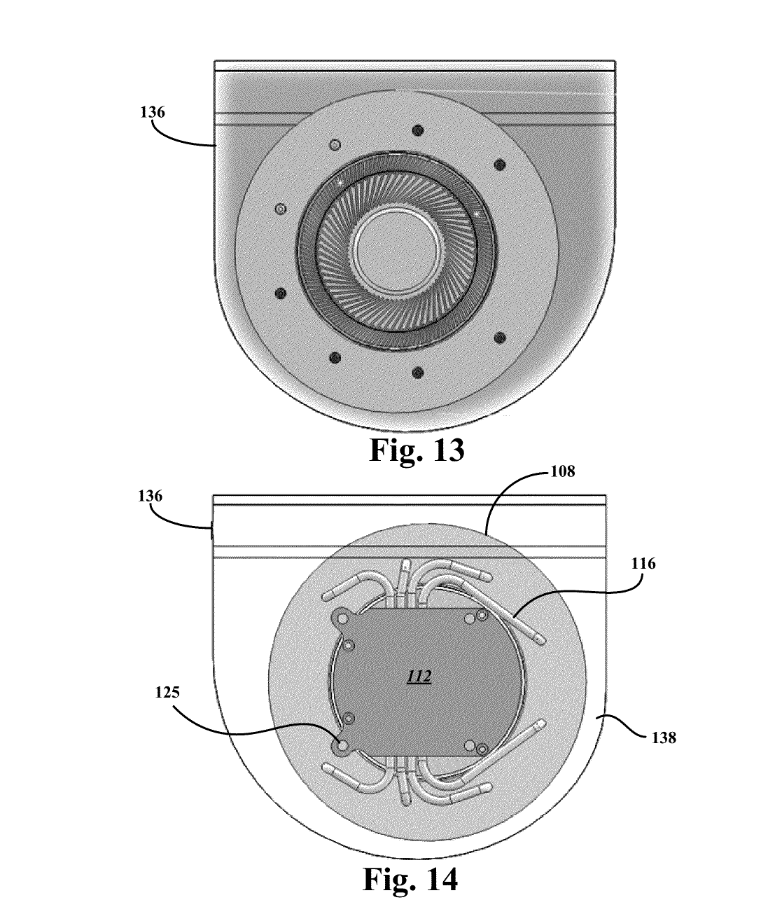

The heat-spreading structures 116 may have different lengths. Additionally, the heat-spreading structures 116 may attach in an asymmetric manner to the stationary fins. FIGS. 11-14 schematically show different views of a kinetic heat-sink 100 with horizontal stationary fins according to an alternative embodiment of the invention. FIG. 14 shows a bottom view of the kinetic heat sink 100 with asymmetric heat-spreading structures 116. The heat-spreading structures 116 may extend from or attach to the thermal base structure 112 at some of the sides of the structures 112. The thermal base structure 112 may include holes 125 for mounting to the printed circuit board or a mounting socket.

The stationary fins 108 may have an outer diameter measuring preferably between about 50 and 200 mm, such as between about 75 and 150 mm, or about 140 mm. The height profile of the stacked stationary fins 108 may measure between about 25 and 50 mm, such as between 25 and 30 mm, or about 26.5 mm. The heat-spreading structures 116 may extend above the stationary fins 108.

The kinetic heat-sink 100 may include a housing or other structure to guide the output flow. Guided-flow output refers to movement of the transfer medium in a channeled manner (i.e., not radial in all directions). In such embodiments, the stationary fins 108 may be configured to use volumes generally not accessible to the rotating structure 102. Accordingly, a kinetic heat sink with a smaller footprint may have comparable cooling capacity as a larger kinetic heat sink without such a feature. Examples of such structures are described in PCT Application No. PCT/US14/030,162, and titled “Kinetic heat sink with stationary fins” and PCT Application No. PCT/US13/72861, filed Dec. 3, 2013, and titled “Kinetic heat-sink-cooled server.” Both of these applications are incorporated by reference herein in their entireties.

FIGS. 12-14 schematically show different view of the kinetic heat sink 100 with a housing 136. The housing 136 may be fixably coupled to the base structure 112, or mounted to other static surfaces proximal to the kinetic heat sink 100. The housing 136 may be shaped to promote or channel fluid flow, including, for example, a spiral or a shell. The housing 136 may have angled internal surfaces to enhance fluid flow and shaped corresponding to the shape of the underlying kinetic heat sink 100. In such embodiments, the housing 136 may form a spacing 138 with the stationary fins 116. The spacing 138 between the wall member of the housing 136 and the kinetic heat sink 100 may have a minimum distance between two opposing surfaces measuring preferably at least about 3 mm in length, such as between about 5 and 10 mm, or about 6 mm. In certain implementations, the space 138 may increase angularly to at least 20 mm, such as between 20 and 50 mm, or about 45 mm. Of course, other dimensions may be employed for different sizes of the rotating structure 104.

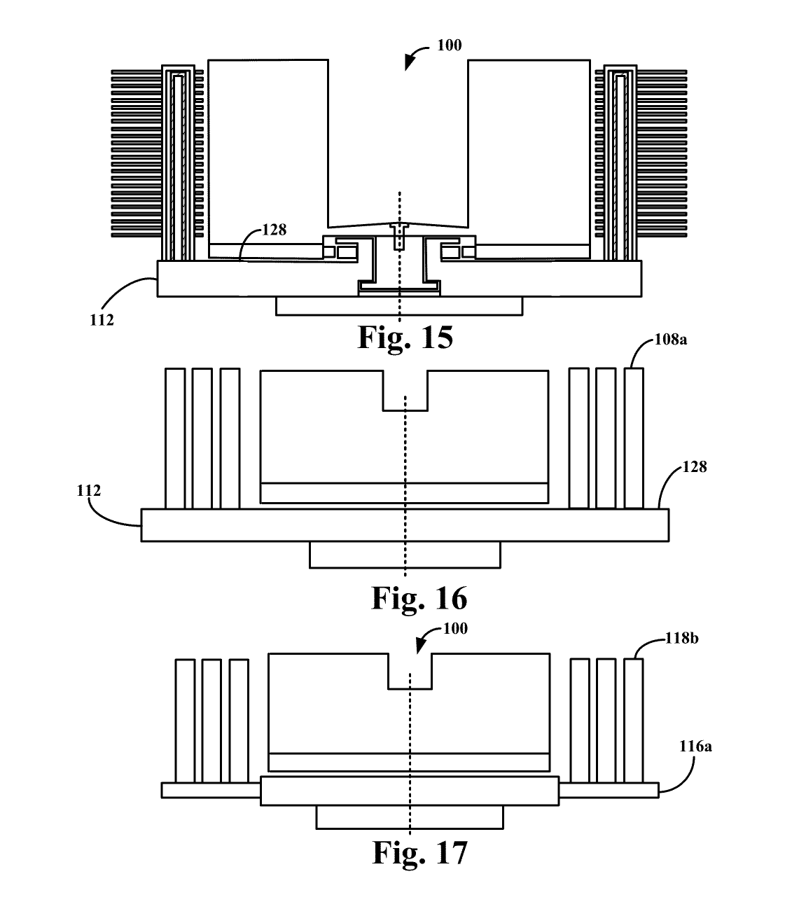

FIG. 15 schematically shows a kinetic heat-sink 100 with orthogonally-oriented stationary fins 108 (i.e., relative to the rotating fins 104 and the base structure 112) according to another embodiment. The stationary fins 108 are fixably attached to the heat-spreading structures 116, which are fixably and directly attached to the surface 128 of the thermal base structure 112.

FIG. 16 schematically shows a kinetic heat-sink 100 with stationary fins 108a according to another embodiment. In this case, the stationary fins 108a are directly coupled to the thermal base structure 112 at the heat transfer surface 128 and, thus, are effectively a part of the thermal base structure 112. Various types of joining means may be employed, including, for example, by chemical means (such as with adhesives), thermal processing means (such as, for example, soldering, blazing, and others), and mechanical means (such as by screw, bolts, clamps, etc.). Alternatively, the stationary fins 108a may be formed as a single structure with the base structure 112—the fins 108a are integrated into the base structure 112. The stationary fins 108a may have surfaces that are angled with respect to the surface of the rotating fins. In certain embodiments, such angle may measure preferably between about 15 and 90 degrees.

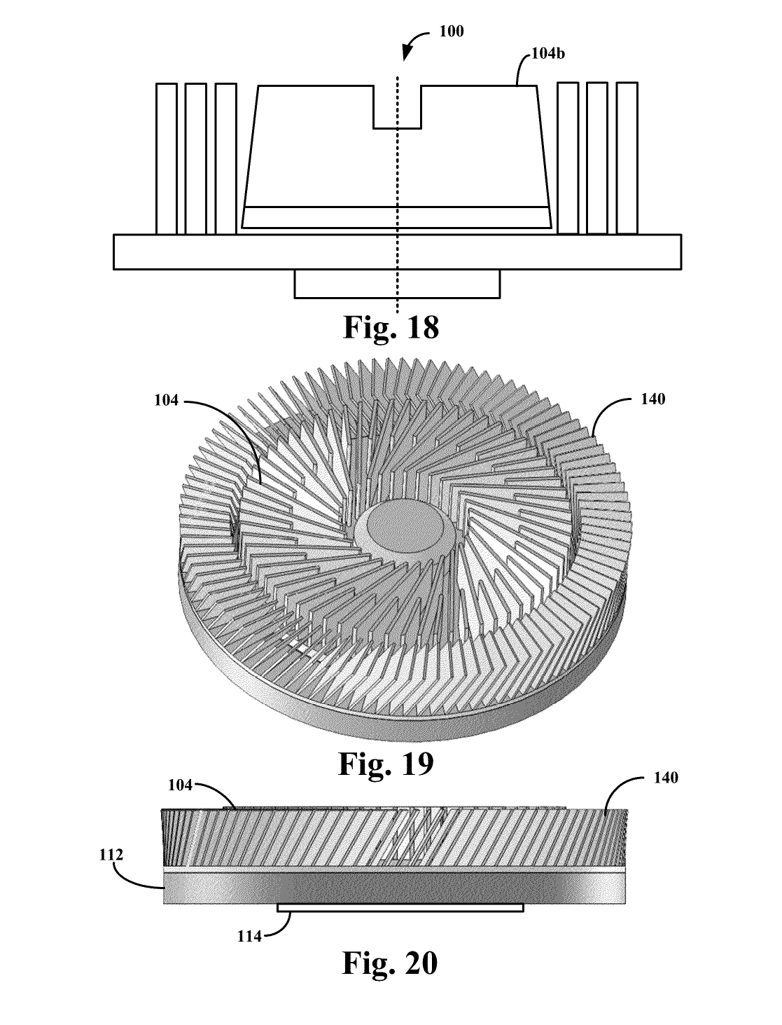

Indeed, illustrative embodiments may employ other types of heat-spreading heat dissipating structures. FIG. 17, for example, illustratively shows the kinetic heat-sink 100 with stationary fins 108b extending from horizontally-oriented heat-spreading structures 116a.

The rotating structure 102 may be configured with rotating fins 104b that are curved or angled (e.g., angled or tapered rotating fin-edges 109). To that end, FIG. 18 illustratively shows a kinetic heat-sink 100 with angled rotating fins 104b. The fins 104b may be vertically oriented (e.g., their faces are generally perpendicular to the generally planar heat-extraction surface 126) with rotating fin-edges 109 that taper to form an angle measuring between about 15 and 60 degrees from the vertical plane. Of course, other angles may be employed as required by the thermal application. To make the straight taper, the width of the fin may be less than the width of the fin nearer the bottom (e.g., see rotating fin 104b of FIG. 18). Some embodiments, however, may vary the taper to a plurality of angles via multiple line segments or other means. Other embodiments may similarly taper the stationary fin-edges 105. Like other embodiments, the fin-edges 105 and 109 of these embodiments may diverge to form a non-parallel orientation.

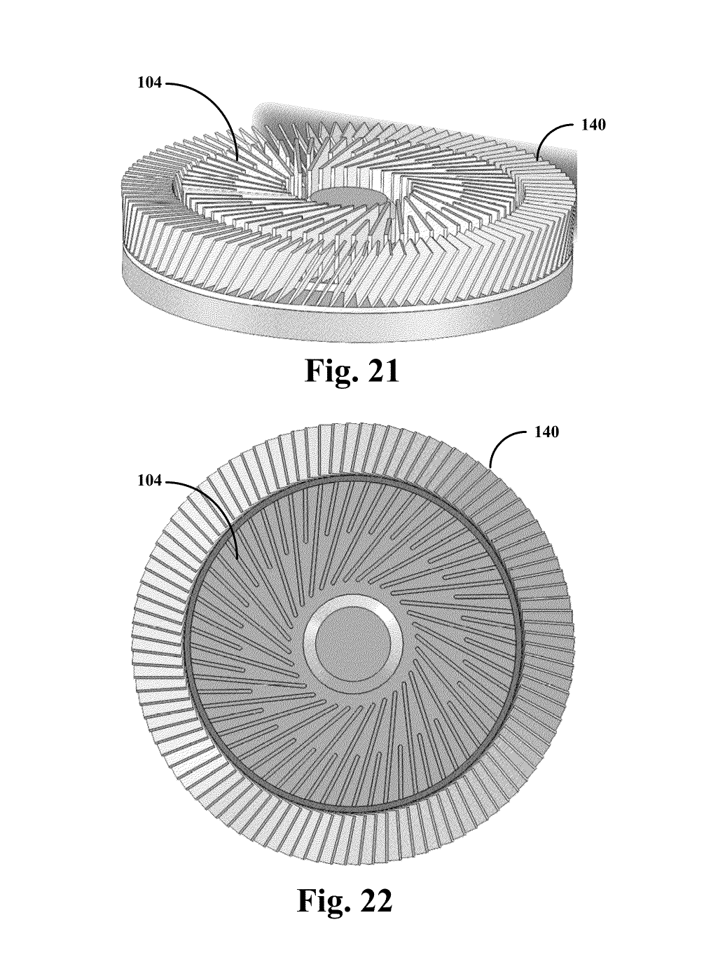

In another embodiment of the embodiment of the invention, the stationary fins may be radially angled. FIGS. 19-22 schematically show different views of a kinetic heat-sink with angled stationary fins 140 according to an alternative embodiment. As shown, the faces of the fins 140 are angled in the appropriate manner. The angled stationary fins 140 may form a radial angle measuring between about 15 and 60 degrees from the vertical plane.

FIG. 23 is a schematic diagram illustrating a thermal-resistance model of the kinetic heat-sink 100 according to the various embodiments. The heat-generating component 114 generates heat (Q:chip). This heat may dissipate to the thermal reservoir 1) through the kinetic portion (i.e., the rotating fins 104) of the kinetic heat-sink 100, 2) through the stationary fins portion (i.e., the stationary fins 108), and 3) by natural convection or radiation. For example, the kinetic heat-sink 100 may dissipate between 40 Watts (W) and 130 Ws of heat (Q:chip) for a power draw of the motor between 3 W and 10 W. Of course, the kinetic heat-sink 100 may be configured with other heat-transfer capacity.

Table 1 provides examples of thermal-resistance characteristics of certain embodiments of the kinetic heat-sink 100.

TABLE 1

| Parameter | Component | Value | |
|---|---|---|---|
| Q: chip | | 76 | W |
| Q: motor | KHS | 1 | W |
| Q: shear | KHS | 0.5 | W |
| R: base_linear | KHS | 0.003 | C/W |
| R: base_spread | KHS | 0.15 | C/W |
| R: motor_spread | KHS | 0.1 | C/W |
| R: fluidgap | KHS | 0.114 | C/W |
| R: platen | KHS | 0.0025 | C/W |
| R: fins | KHS | 0.005 | C/W |
| R: rejection | KHS | 0.4 | C/W |
| R: leak | Leakage | 20 | C/W |
| R: contact_base | Stationary | 0.01 | C/W |
| R: heat_pipes | Stationary | 0.033 | C/W |
| R: contact_fins | Stationary | 0.002 | C/W |
| R: fins | Stationary | 0.005 | C/W |
| R: rejection | Stationary | 0.25 | C/W |

The thermal resistance of the kinetic portion may include a resistance across the thermal base structure 112, the fluid gap 130, and the rotating structure 102 to the thermal reservoir. The thermal resistance of the base structure 112 may be characterized as having a linear component (R:base_linear) and a spreading component (R:base_spread) that is radial to the linear component. The heat generated by the motor assembly 122 (Q:motor) and by longitudinal fluid gap 130 (Q:shear) contributes to the overall heat to be removed by the kinetic heat-sink 100. The heat contribution to the motor assembly 122 and the longitudinal fluid gap 130 may be modeled as internal heat sources (Q:shear and Q:motor) passed through effective resistances R:motor_spread and R:fluidgap. In certain embodiments, this contribution (Q:motor and Q:shear) may be negligible. The rotating plate of the rotating structure 102 has a thermal resistance (R:platen), and the rotating fins 104 have a thermal resistance (R:fins). The heat rejection among the surfaces of the fins 104, 108 and the transfer medium has a thermal resistance (R:rejection). In contrast to the kinetic portion of the heat-sink, the thermal resistance of the stationary fins 108 merely includes that of the stationary fins 108 (R:fins), the heat spreading structure 116 (R:heatpipe), the contact resistance (R:contact_base) between the heat spreading structure 116 and the baseplate 112, the contact resistance (R:contact_fins) between the heat spreading structure 116 and the stationary fins 108, and the heat rejection (R:rejection).

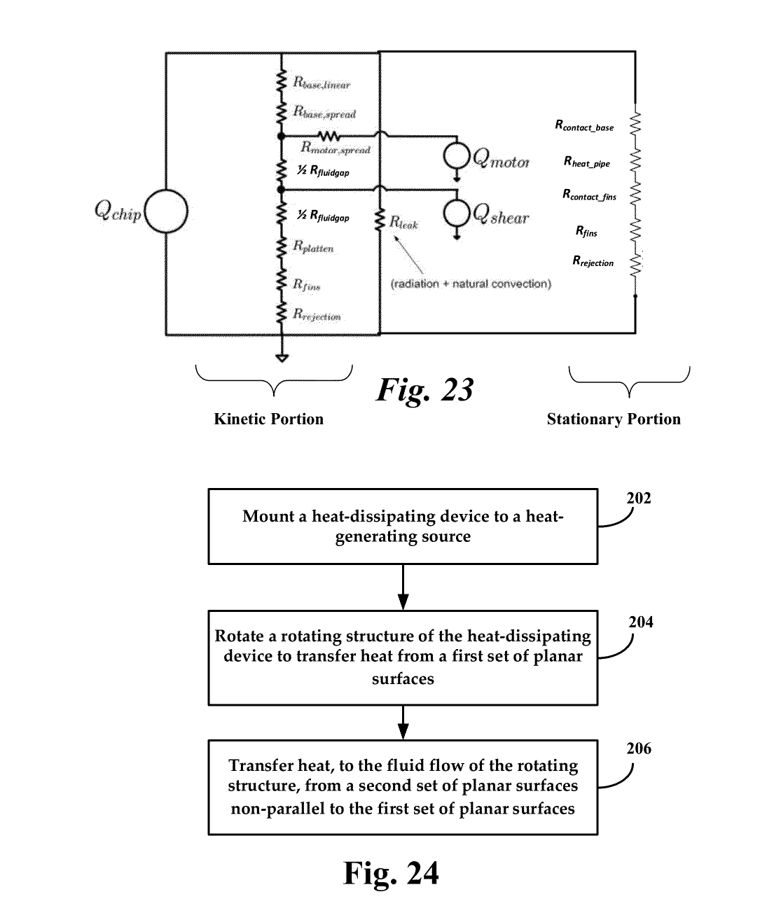

FIG. 24 shows a method of operating a kinetic heat-sink according to an illustrative embodiment. The method provides a kinetic heat-sink 100 having a base structure 112, a rotating structure 102, and stationary fins 108 as discussed above. The kinetic heat-sink 100 may be mounted to a printed circuit-board supporting the heat-generating component by various means, such as clamps, screws, bolts, adhesives, etc. (step 202). The base structure 112 has a first heat-conducting surface 113 and a second heat-conducting surface 128 (e.g., see FIG. 2) to conduct heat therebetween. The first heat-conducting surface 113 is mountable to the heat-generating component 114. The rotating structure 102 rotatably couples with the base structure 112 and its movable heat-extraction surface 126 facing the second heat-conducting surface 128 across the longitudinal fluid gap 130.

The rotating structure 102 rotates, causing the rotating fins 104 to channel a heat-transfer fluid from a region (i.e., first area) of the thermal reservoir communicating with the rotating structure 102 to another area (i.e., second area) of the thermal reservoir (step 204). The fluid generally expels outwardly and radially from the rotating structure 102. The stationary fins 108 are in thermal contact with the base structure 112 through, for example, the heat-spreading structures 116 and are in the path of fluid flow between the first area and the second area of the thermal reservoir. As the fluid flows from the rotating structure 102, the stationary fins 108 transfer heat from its surfaces, which may be generally planar, to the flow from the rotating structure 102 (step 206). The heat-transfer forms a thermal-gradient between the thermal base 112 and both the rotating and stationary fins 104, 108 to draw heat from the heat-generating component 114.

The method may also vary the speed of rotation of the rotating structure 102 to control an amount of heat-transfer from the stationary fins 108 in the path of the fluid flow and the heat-transfer from the rotating fins 104. For example, the method may maximize Q-total of Equations 3 or 4. The controls may be based on models of the thermal-resistance characteristics of a kinetic heat-sink as illustrated in FIG. 19. Alternatively, or in addition to, the method may minimize or reduce a noise level as generated by the kinetic heat-sink 100 during its operation.

Various embodiments of the kinetic heat-sink 100 may be similar to the kinetic heat-sink disclosed in U.S. Provisional Patent Application No. 61/66,868 having the title “Kinetic Heat Sink Having Controllable Thermal Gap” filed Jun. 26, 2012, and U.S. Provisional Patent Application No. 61/713,774 having title “Kinetic Heat Sink with Sealed Liquid Loop” filed Nov. 8, 2012. These patent applications are incorporated herein by reference in their entireties.

Although the above discussion discloses various exemplary embodiments of the invention, it should be apparent that those skilled in the art can make various modifications that will achieve some of the advantages of the invention without departing from the true scope of the invention.

What is claimed is:

1. A kinetic heat sink comprising:
a base;
a rotating structure rotatably coupled with the base, the base and rotating structure forming a kinetic heat sink, the rotating structure having a movable heat-extraction surface spaced from and facing the base across a longitudinal fluid gap, the rotating structure having a plurality of rotating fins in thermal contact with the movable heat extraction surface and configured to move fluid, each of the plurality of rotating fins having a rotating fin-edge; and
a plurality of stationary fins in thermal contact with the base, the plurality of stationary fins being positioned radially outward of the rotating fins, each of the plurality of stationary fins having a stationary fin-edge that is its most radially inward portion, the plurality of stationary fin-edges and the plurality of rotating fin-edges forming a circumferential fluid gap radially outward of the plurality of rotating fins,
at least a portion of the stationary fin-edge of one of the stationary fins being non-parallel to at least a portion of the rotating fin-edge of at least one of the rotating fins.

2. The kinetic heat sink as defined in claim 1, wherein at least a portion of the stationary fin-edge of at least one of the stationary fins is substantially perpendicular to at least a portion of the rotating fin-edge of at least one of the rotating fins.

3. The kinetic heat sink as defined in claim 2, wherein the stationary fin-edges of the plurality of stationary fins are substantially perpendicular to the rotating fin-edges of the plurality of rotating fins.

4. The kinetic heat sink as defined in claim 1, wherein the base includes a generally planar top base surface facing the rotating structure, each of the plurality of stationary fin-edges having at least a portion that forms an angle with the generally planar top base surface, the angle measuring between about 0 and 60 degrees.

5. The kinetic heat sink as defined by claim 1 wherein the movable heat-extraction surface includes a rotatable, generally planar top surface configured to rotate in a rotation plane, each of the plurality of rotating fin-edges having at least a portion that is substantially perpendicular to the rotation plane.

6. The kinetic heat sink as defined by claim 5 wherein each of the plurality of stationary fin-edges has at least a portion that is substantially parallel to the rotation plane of the movable heat-extraction surface.

7. The kinetic heat sink as defined by claim 5 wherein each of the plurality of stationary fin-edges has at least a portion that forms an angle with the rotation plane of the movable heat-extraction surface, the angle being between about 0 and 60 degrees.

8. The kinetic heat sink as defined by claim 1 wherein the movable heat-extraction surface includes a rotatable, generally planar top surface configured to rotate in a rotation plane,
further wherein each of the rotating fins has a face with an upper and lower portion relative to the generally planar top surface, each of the rotating fins having an upper width nearer its upper portion and a lower width nearer its lower portion, the upper width of each rotating fin being less than its lower width to form a tapering rotating fin-edge.

9. The kinetic heat sink as defined by claim 1 wherein the base includes a generally planar top base surface facing the rotating structure,
further wherein each of the stationary fins has a face with an upper and lower portion relative to the generally planar top base surface, each of the stationary fins having an upper width nearer its upper portion and a lower width nearer its lower portion, the upper width of each stationary fin being less than its lower width to form a tapering stationary fin-edge.

10. The kinetic heat sink as defined by claim 1 wherein each rotating fin has a tapering rotating fin-edge and each stationary fin has a tapering stationary fin-edge.

11. The kinetic heat sink as defined by claim 1 wherein the plurality of rotating fins are in conductive heat contact with the movable heat extraction surface.

12. The kinetic heat sink as defined by claim 1 wherein the plurality of stationary fins are in conductive heat contact with the base.

13. The kinetic heat sink as defined by claim 1 wherein the movable heat-extraction surface includes a rotatable, generally planar top surface configured to rotate in a rotation plane,
further wherein each of the plurality of rotating fins has a substantially identical cross-sectional shape in planes parallel to the rotation plane.

14. The kinetic heat sink as defined in claim 1 further comprising a heat-spreading member convectively coupled between the base and the stationary fins.

15. The kinetic heat sink as defined in claim 1, wherein the rotating structure is configured to rotate to move fluid, the plurality of stationary fins being oriented and configured to dissipate heat when in contact with the fluid moved by the plurality of rotating fins.

16. The kinetic heat sink as defined in claim 1, wherein the longitudinal fluid gap is less than about 150 micrometers.

17. The kinetic heat sink as defined by claim 1 wherein at least a portion of the circumferential fluid gap is at least about 2 millimeters.

18. The kinetic heat sink as defined by claim 1 wherein the plurality of stationary fins comprises a stacked plurality of ring shaped members having faces that are substantially parallel to the base, each stationary fin being spaced from the other stationary fins.

19. A kinetic heat sink comprising:
a base;
a rotating structure rotatably coupled with the base, the base and rotating structure forming a kinetic heat sink, the rotating structure having a movable heat extraction surface and plurality of rotating fins in thermally conductive contact with the movable heat extraction surface, each of the plurality of rotating fins having a radially outermost rotating fin-edge; and
a plurality of stationary fins in thermally conductive contact with the base, the plurality of stationary fins circumscribing the plurality of rotating fins, each of the plurality of stationary fins having a stationary fin-edge that is its most radially inward portion, the plurality of stationary fin-edges and plurality of rotating fin-edges forming a circumferential fluid gap radially outward of the plurality of rotating fins,
at least a portion of the stationary fin-edge of one or more of the stationary fins diverges from at least a portion of the rotating fin-edge of at least one of the rotating fins.

20. The kinetic heat sink as defined by claim 19 wherein the plurality of rotating fins are in thermally convective contact with the plurality of stationary fins.

21. The kinetic heat sink as defined by claim 19 wherein each rotating fin-edge is the most radially outward portion of its rotating fin.

22. The kinetic heat sink as defined in claim 19, wherein at least a portion of the stationary fin-edge of at least one of the stationary fins is substantially perpendicular to at least a portion of the rotating fin-edge of at least one of the rotating fins.

23. The kinetic heat sink as defined in claim 22, wherein the stationary fin-edges of the plurality of stationary fins are substantially perpendicular to the rotating fin-edges of the plurality of rotating fins.

24. The kinetic heat sink as defined in claim 19, wherein the base includes a generally planar top base surface facing the rotating structure, each of the plurality of stationary fin-edges having at least a portion that forms an angle with the generally planar top base surface, the angle measuring between about 0 and 60 degrees.

25. The kinetic heat sink as defined by claim 19 wherein the movable heat-extraction surface includes a rotatable, generally planar top surface configured to rotate in a rotation plane, each of the plurality of rotating fin-edges having at least a portion that is substantially perpendicular to the rotation plane.

26. The kinetic heat sink as defined by claim 19 wherein the movable heat-extraction surface includes a rotatable, generally planar top surface configured to rotate in a rotation plane,
further wherein each of the rotating fins has a face with an upper and lower portion relative to the generally planar top surface, each of the rotating fins having an upper width nearer its upper portion and a lower width nearer its lower portion, the upper width of each rotating fin being less than its lower width to form a tapering rotating fin-edge.

27. The kinetic heat sink as defined by claim 19 wherein the base includes a generally planar top base surface facing the rotating structure,
further wherein each of the stationary fins has a face with an upper and lower portion relative to the generally planar top base surface, each of the stationary fins having an upper width nearer its upper portion and a lower width nearer its lower portion, the upper width of each stationary fin being less than its lower width to form a tapering stationary fin-edge.

28. A kinetic heat sink comprising:
a base;
a rotating structure rotatably coupled with the base, the base and rotating structure forming a kinetic heat sink,
the rotating structure having a generally planar rotatable heat extraction surface, the rotating structure also having plurality of rotating fins in thermally conductive contact with the rotatable heat extraction surface, each of the plurality of rotating fins having a radially outermost rotating fin-edge that is substantially perpendicular to the planar rotatable heat extraction surface; and
a plurality of stationary fins in thermally conductive contact with the base, the plurality of stationary fins circumscribing the plurality of rotating fins, each of the plurality of stationary fins having a stationary fin-edge that is its most radially inward portion, the plurality of stationary fin-edges and plurality of rotating fin-edges forming a circumferential fluid gap radially outward of the plurality of rotating fins,
at least a portion of the stationary fin-edge of one or more of the stationary fins forms an angle of between about 30 and 90 degrees with the rotating fin-edge of one or more of the rotating fins.

29. The kinetic heat sink as defined by claim 28 wherein the movable heat-extraction surface includes a rotatable, generally planar top surface configured to rotate in a rotation plane, further wherein each of the plurality of stationary fin-edges has at least a portion that forms an angle with the rotation plane of the movable heat-extraction surface, the angle being between about 0 and 60 degrees.

30. The kinetic heat sink as defined by claim 28 wherein the plurality of stationary fins are tapered and the plurality of rotating fins are tapered.
